(19) United States
(12) Patent Application Publication
(10) Pub. No.: US 2024/0055555 A1
(43) Pub. Date: Feb. 15, 2024

(54) COMPOSITE SUBSTRATES AND SEMICONDUCTOR DEVICE STRUCTURES

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 18/448,193

(22) Filed: Aug. 11, 2023

(30) Foreign Application Priority Data
Aug. 12, 2022 (CN) 202222129523.9

(51) Int. Cl. H01L 33/10

(52) U.S. Cl. CPC H01L 33/10

(57) ABSTRACT

The present disclosure provides a composite substrate and semiconductor device structure, where the composite substrate includes: a base; a DBR layer on a side of the base; and a growing substrate on a side of the DBR layer far from the base. In the present disclosure, the growing substrate can be prepared on the top layer of the DBR layer by a bonding process, which requires a lower temperature than the high-temperature epitaxial process, reducing the risk of DBR layer decomposition during the preparation of the growing substrate, thereby, improving the stability of the DBR layer.

### CROSS REFERENCE TO RELATED APPLICATIONS

This application claims priority to Chinese Patent Application No. 2022221295239 filed on Aug. 12, 2022, the entire content of which is incorporated herein by reference.

### TECHNICAL FIELD

The present disclosure relates to the technical field of semiconductor optoelectronic technologies, in particular to composite substrates and semiconductor device structures.

### BACKGROUND

LED (light emitting diode) has characteristics of energy conservation, environmental protection, long lifespan and small size, and is widely used in various fields such as indicating lighting, display, decorating lighting, backlight, general lighting, and urban night scenery.

Generally, DBR (distributed Bragg reflector) layer is one of main components of LEDs. The DBR layer is a periodic structure composed of two materials with different reflectivity arranged alternately. The DBR layer is usually applied to semiconductor device structures, such as LEDs, to enhance the brightness of LEDs and achieve energy-saving effects. For example, in the Chinese patent with patent number CN102683532B, a substrate containing a structure of a patterned DBR layer is mentioned, where the patterned DBR layer is set on a surface of the substrate and a LED device structure is directly epitaxially grown. However, in a process of preparing LED, it is necessary to prepare other structural layers on the DBR layer through high-temperature epitaxial process. The high-temperature epitaxial process requires a higher temperature, which can easily decompose the DBR layer and reduce a stability of the DBR layer.

### SUMMARY

The present disclosure provides a composite substrate, including: a base; a DBR (distributed Bragg reflector) layer on a side of the base; and a growing substrate on a side of the DBR layer far from the base.

In some embodiments, the composite substrate further includes a protecting layer, where the protecting layer covers a top surface of the DBR layer, or the protecting layer covers a top surface and a side surface of the DBR layer.

In some embodiments, a light transmittance of light of at least one wavelength passing through the protecting layer and the growing substrate exceeds 70%.

In some embodiments, the base includes a patterned base, and the top surface of the base is provided with a trench, and the DBR layer is in the trench.

In some embodiments, the DBR layer protrudes from the top surface of the base; a top surface of the DBR layer is flush with the top surface of the base; or a top surface of the DBR layer is lower than the top surface of the base.

In some embodiments, the composite substrate further includes a protecting layer, where the protecting layer only covers the DBR layer, and the growing substrate is bonded to the base; or the protecting layer covers the DBR layer and the base, and the growing substrate is bonded to the protecting layer.

In some embodiments, a top surface of the protecting layer is flush with the top surface of the base, and the growing substrate is bonded with the protecting layer and the base.

In some embodiments, a material of the protecting layer includes at least one of Si, AlO, or AN.

In some embodiments, a material of the base includes at least one of Si, SiC, AlO, or Diamond.

In some embodiments, the growing substrate includes a monocrystalline-material layer.

In some embodiments, a material of the growing substrate includes at least one of Si, AlO, or AlN.

In some embodiments, the material of the growing substrate is Si, a thickness of the growing substrate is less than 100 nm.

In some embodiments, a material of the DBR layer includes a SiN layer and a SiO₂ layer that are periodically stacked, a SiO₂ layer and an Al₂O₃ layer that are periodically stacked, an AlN layer and an Al₂O₃ layer that are periodically stacked, or a fluorine doped SiO₂ layer and a SiO₂ layer that are periodically stacked.

The present disclosure further provides a semiconductor device structure, including a composite substrate and an LED unit, where the composite substrate includes: a base; a DBR layer on a side of the base; and a growing substrate on a side of the DBR layer far from the base; and the LED unit includes: a first semiconductor layer, on the growing substrate; an active layer, on a surface of the first semiconductor layer; and a second semiconductor layer, on a surface of the active layer; where conductive types of the first semiconductor layer and the second semiconductor layer are opposite.

In some embodiments, the base is provided with a plurality of the DBR layers, and there are a plurality of the LED units, each of the plurality of the LED units corresponds to one of the plurality of the DBR layers.

In some embodiments, the composite substrate includes a plurality of the DBR layers, and at least one of: cross-sectional areas of the plurality of the DBR layers are different; or spaces between adjacent DBR layers of the plurality of the DBR layers are different.

The beneficial effects of the technical solutions provided in the embodiments of the present disclosure are described below.

The growing substrate can be prepared on the top layer of the DBR layer by a bonding process, which requires a lower temperature than the high-temperature epitaxial process, reducing the risk of DBR layer decomposition during the preparation of the growing substrate, thereby, improving the stability of the DBR layer. At the same time, the DBR layer is integrated into the substrate, which has little impact on the performance of the DBR layer and the substrate.

Moreover, the growing substrate is prepared by a bonding process. Compared to the epitaxial process, the bonding process is simple and cost-effective, which can effectively reduce the preparation cost for the composite substrate.

It is to be understood that the above general descriptions and the below detailed descriptions are merely exemplary and explanatory, and are not intended to limit the present disclosure.

### BRIEF DESCRIPTION OF DRAWINGS

FIG. 1 is a first structural schematic diagram of a composite substrate according to embodiments of the present disclosure.

FIG. 2 is a second structural schematic diagram of a composite substrate according to embodiments of the present disclosure.

FIG. 3 is a third structural schematic diagram of a composite substrate according to embodiments of the present disclosure.

FIG. 4 is a fourth structural schematic diagram of a composite substrate according to embodiments of the present disclosure.

FIG. 5 is a fifth structural schematic diagram of a composite substrate according to embodiments of the present disclosure.

FIG. 6 is a sixth structural schematic diagram of a composite substrate according to embodiments of the present disclosure.

FIG. 7 is a seventh structural schematic diagram of a composite substrate according to embodiments of the present disclosure.

FIG. 8 is a first structural schematic diagram of a semiconductor device according to embodiments of the present disclosure.

FIG. 9 is a second structural schematic diagram of a semiconductor device according to embodiments of the present disclosure.

FIG. 10 is a third structural schematic diagram of a semiconductor device according to embodiments of the present disclosure.

FIG. 11 is a fourth structural schematic diagram of a semiconductor device according to embodiments of the present disclosure.

### DETAILED DESCRIPTION

Exemplary embodiments will be described in detail herein, examples of which are illustrated in the accompanying drawings. Where the following description refers to the drawings, elements with the same numerals in different drawings refer to the same or similar elements unless otherwise indicated. Embodiments described in the illustrative examples below are not intended to represent all embodiments consistent with the present disclosure. Rather, they are merely embodiments of devices and methods consistent with some aspects of the present disclosure as recited in the appended claims.

Terms used in the present disclosure is only for the purpose of describing particular embodiments and is not intended to limit the present disclosure. As used in the present disclosure and the appended claims, the singular forms “a”, “said” and “the” are intended to include the plural” and “the” are intended to include the plural forms as well, unless the context clearly dictates otherwise. It should further be understood that the term “and/or” as used herein refers to and includes any and all possible combinations of one or more of the associated listed items.

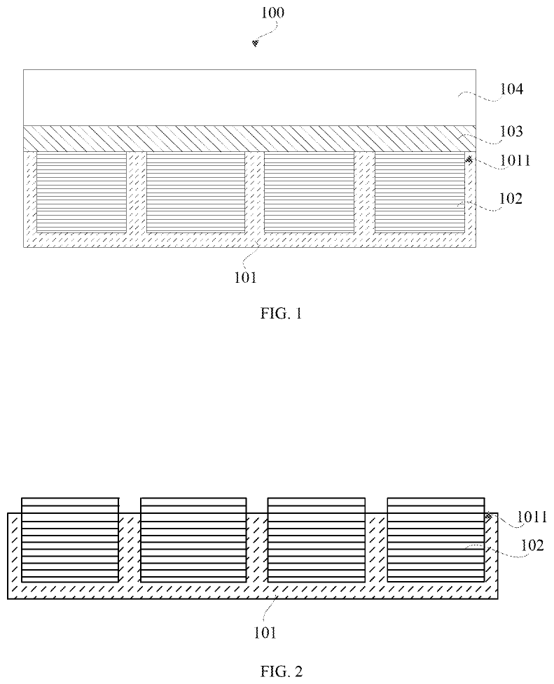

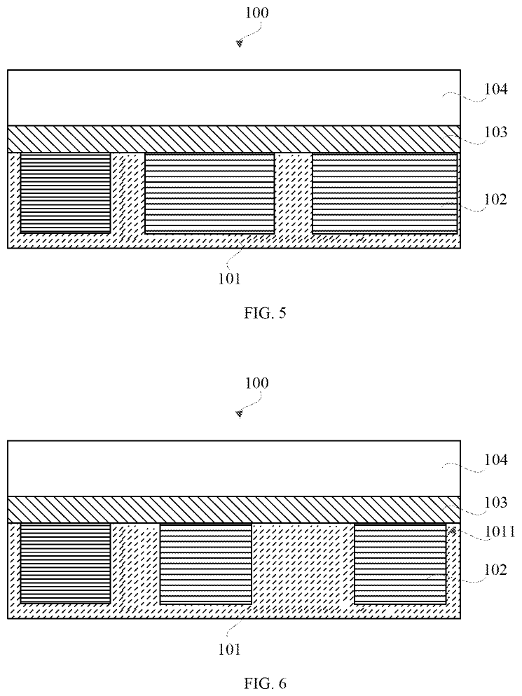

As shown in FIGS. 1 to 7, the composite substrate 100 provided in the present disclosure is provided with a DBR (distributed Bragg reflector) layer 102. The composite substrate 100 can play a supporting and fixing role in the production and preparation of a semiconductor device structure. The DBR layer 102 can enhance the brightness of a semiconductor device structure and achieve energy-saving effects during the use of a semiconductor device structure. The DBR layer 102 is prepared in the composite substrate 100, which can reduce the risk of the DBR layer 102 decomposition and improve the stability of the DBR layer 102.

To achieve the above objectives, the composite substrate 100 can be set in various ways. The following, taking embodiments as examples, is a detailed introduction to the construction of the composite substrate 100.

In a first embodiment, as shown in FIG. 1, the composite substrate 100 includes a base 101, a DBR layer 102 and a growing substrate 103 that are prepared sequentially. For example, by patterning the base 101 through a mask etching process, a trench 1011 is formed in the base 101.

An opening of the trench 1011 faces a top surface of base 101. A depth of the trench 1011 can be set according to requirements. In an embodiment, the depth of the trench 1011 is 0.5-0.9 times a thickness of the base 101, for example, the depth of the trench 1011 can be 0.5, 0.7 or 0.9 times the thickness of the base 101.

A shape of the trench 1011 can be set according to requirements. In an embodiment, a cross-section of trench 1011 may be a regular shape, such as a rectangle, a square or a circle, or other irregular shapes. The cross-section of the trench 1011 is parallel to the top surface of base 101.

At least one trench 1011 can be formed in the base 101. In an embodiment, at least two trenches 1011 are formed at intervals in the base 101, with an opening of each trench 1011 facing the top surface of the base 101.

When at least two trenches 1011 are formed in the base 101, a depth of each trench 1011 and a space between adjacent trenches 1011 can be set according to requirements. In an embodiment, a shape, a size, and a depth of each trench 1011 are the same, and the cross-section of each trench 1011 is square, circular, or hexagonal. In other embodiments, the cross-section of each trench 1011 is unequal and/or the space between adjacent trenches 1011 is unequal, resulting in unequal cross-sectional areas of multiple DBR layers 102 prepared in trenches 1011 and/or unequal spaces between adjacent DBR layers 102, to meet various usage needs.

A material of base 101 can be polycrystalline or monocrystalline to meet various usage needs. For example, a material of base 101 can be in polycrystalline form of Si (silicon), Al₂O₃ (sapphire), AlN (aluminum nitride), Diamond, or SiC (silicon carbide), or in monocrystalline form of Si, Al₂O₃, AlN, diamond, or SiC. The base 101 using SiC material has mature production technology, good device quality, high stability, high mechanical strength, and is easy to dispose and clean. The base 101 using Si material has excellent thermal conductivity and extends the lifespan of the device. The base 101 using AlN material has excellent thermal, mechanical, chemical, and electrical properties, which is not only one of the best materials for preparing high-temperature, high-frequency and high-power electronic devices, but also can be used as a substrate material for GaN based blue semiconductor device structures.

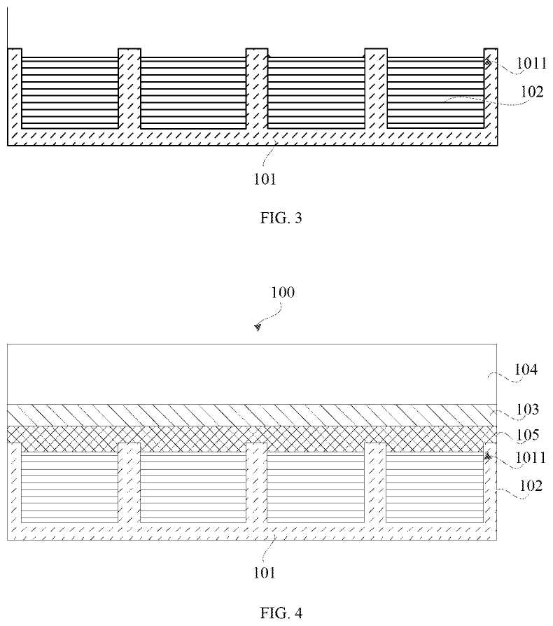

The DBR layer 102 is prepared in each trench 1011 of the base 101. The top surface of the DBR layer 102 can be flush with the top surface of the base 101. As shown in FIG. 2, the top surface of the DBR layer 102 can also protrude from the top surface of base 101. As shown in FIG. 3, the top surface of the DBR layer 102 can also be lower than the top surface of base 101.

When the DBR layer 102 is prepared, the DBR layer 102 is first prepared thicker, and then the DBR layer 102 is subjected to Chemical Mechanical Polishing (CMP) to ensure the flatness of the growing substrate 103 located on the top surface of the DBR layer 102.

The material of the DBR layer 102 includes a SiN layer and a SiO₂ layer that are periodically stacked, a SiO₂ layer and an Al₂O₃ layer that are periodically stacked, an AlN layer and an Al₂O₃ layer that are periodically stacked, or a fluorine doped SiO₂ layer and a SiO₂ layer that are periodically stacked, to meet various usage needs.

The growing substrate 103 is prepared on the top surface of the base 101 through a bonding process, i.e., the growing substrate 103 is bonded to the base 101. The temperature required by the bonding process is lower than the temperature required by the high-temperature epitaxial process, reducing the risk of the DBR layer 102 decomposition during the preparation of the growing substrate 103, thereby improving the stability of the DBR layer 102.

A material of the growing substrate 103 is at least one of Si, SiC, Al₂O₃, AlN, or GaN, to meet various usage needs. When the material of the growing substrate 103 is Si, the thickness of the growing substrate 103 is less than 100 nm to ensure the transparency of the growing substrate 103. In an embodiment, the material of the growing substrate 103 is Si, and the thickness of the growing substrate 103 is 40-60 nm, such as 40 nm, 50 nm, or 60 nm.

The composite substrate 100 further includes a buffer layer 104, which is prepared on the top surface of the growing substrate 103, i.e., the buffer layer 104 is prepared on a side of the growing substrate 103 far from the DBR layer 102. The buffer layer 104 plays a transitional role for the subsequent epitaxial structure and a heteroepitaxy on the growth substrate, so as to improve the crystal quality of the subsequent epitaxial structure.

The buffer layer 104 can be grown on the growing substrate 103 through epitaxial process. The preparation cost of the buffer layer 104 is low, and the preparation process is mature, which ensures the performance of the composite substrate 100.

A material of the buffer layer 104 is group III nitride. In an embodiment, a material of the buffer layer 104 includes AlN, GaN, or AlGaN.

The steps of preparing the composite substrate 100 include steps S10-S30.

In step S10, a base 101 is provided and the base 101 is patterned to form a trench 1011.

In step S20, a DBR layer 102 is prepared in the trench 1011.

In step S30, a growing substrate 103 is provided, and the growing substrate 103 is bonded to a surface of a patterned side of the base 101.

In some embodiments, the steps of preparing the composite substrate 100 further includes step S40. In step S40, the buffer layer 104 is epitaxially grown on the top surface of the growing substrate 103.

In step S20, when the DBR layer 102 is prepared, the last film layer of the DBR layer 102 is first prepared to be higher than the base 101, and then the DBR layer 102 is subjected to chemical mechanical polishing to ensure the flatness of the growing substrate 103 located on the top surface of the DBR layer 102.

In a second embodiment of the present disclosure, as shown in FIGS. 4 to 6, this embodiment is basically the same as the above embodiments, and the same parts is not repeated. The difference is that in this embodiment, there is further a protecting layer 105 between the DBR layer 102 and the growing substrate 103. The protecting layer 105 is prepared through a deposition process, which requires a lower temperature to ensure that the DBR layer 102 is not damaged during the preparation process.

The protecting layer 105 is prepared on the top surface of the DBR layer 102, is transparent and protects the DBR layer 102. In an embodiment, the DBR layer 102 is lower than the base 101, and the protecting layer 105 is located in the trench 1011. After the protecting layer 105 is prepared, the top surface of the protecting layer 105 is flush with the top surface of the base 101, that is, the protecting layer 105 only covers the DBR layer 102 and does not cover the base 101.

In another embodiment, the DBR layer 102 is flush with or higher than the base 101. After the protecting layer 105 is prepared, the top surface of the protecting layer 105 protrudes from the base 101 and covers both the DBR layer 102 and the base 101. The protecting layer 105 protects the DBR layer 102 and improves the bonding effect of the growing substrate 103.

No matter how the protecting layer 105 is set, the DBR layer 102 can be subjected to chemical mechanical polishing, and the protecting layer 105 can also be subjected to chemical mechanical polishing. If the protecting layer 105 is subjected to chemical mechanical polishing, when the protecting layer 105 is prepared, the protecting layer 105 is first prepared thicker, and then the protecting layer 105 is subjected to chemical mechanical polishing until the protecting layer 105 reaches the required thickness to ensure the flatness of the growing substrate 103 located in the upper layer.

If the DBR layer 102 is subjected to chemical mechanical polishing, when the DBR layer 102 is prepared, the film layer of DBR layer 102 is first prepared thicker, and then the DBR layer 102 is subjected to chemical mechanical polishing.

No matter how the protecting layer 105 is set, a light transmittance of light of at least one wavelength passing through the protecting layer 105 and the growing substrate 103 exceeds 70%, reducing light loss. In an embodiment, a material of the protecting layer 105 can be at least one of Si, Al₂O₃, or AlN, to meet various usage needs. The protecting layer 105 is deposited on the top surface of the DBR layer 102 through the PVD (Physical vapor deposition) process. The temperature required by the PVD process is lower than the temperature required by the high-temperature epitaxial growth process, reducing the risk of decomposition of the DBR layer 102, thus improving the stability of the DBR layer 102.

It should be noted that when the material of the protecting layer 105 is Si, the thickness of a part of the protecting layer 105 at the DBR layer 102 is less than 100 nm, to ensure the transparency of the protecting layer 105. In an embodiment, the material of the protecting layer 105 is Si, and the thickness of a part of the protecting layer 105 at the DBR layer 102 is 40-60 nm, such as 40 nm, 50 nm, or 60 nm.

The growing substrate 103 was prepared through a bonding process. When the protecting layer 105 is flush with the base 101, the growing substrate 103 is bonded with the protecting layer 105 and the base 101. When the protecting layer 105 covers the base 101, the growing substrate 103 is bonded to the protecting layer 105. The bonding process is simple and cost-effective, which can effectively reduce the preparation cost of the composite substrate 100.

The steps of preparing the composite substrate 100 include steps S10-S50.

In step S10, a base 101 is provided and the base 101 is patterned to form a trench 1011.

In step S20, a DBR layer 102 is prepared in the trench 1011.

In step S30, a protecting layer 105 is prepared on the DBR layer 102.

In step S40, a growing substrate 103 is provided, and the growing substrate 103 is bonded to a surface of a patterned side of the base 101.

In step S50, the buffer layer 104 is epitaxially grown on the top surface of the growing substrate 103.

In step S20, the DBR layer 102 is concave relatively to the base 101. When the DBR layer 102 is prepared, chemical mechanical polishing may be performed on the DBR layer 102, or chemical mechanical polishing may not be performed on the DBR layer 102. If the DBR layer 102 is subjected to chemical mechanical polishing, when the DBR layer 102 is prepared, the last film layer of the DBR layer 102 is first prepared thicker, and then the DBR layer 102 is subjected to chemical mechanical polishing.

In step S30, if the DBR layer 102 is subjected to chemical mechanical polishing, the protecting layer 105 may not be subjected to chemical mechanical polishing to reduce the preparation process and cost. If the DBR layer 102 is not subjected to chemical mechanical polishing, then the protecting layer 105 is subjected to chemical mechanical polishing. Before the chemical mechanical polishing is performed on the protecting layer 105, the protecting layer 105 is prepared thicker, and then the protecting layer 105 is subjected to chemical mechanical polishing until the protecting layer 105 reaches the required thickness.

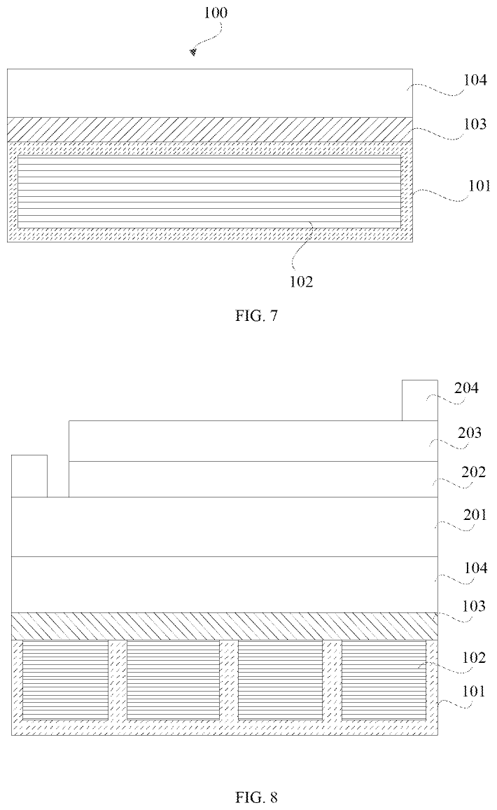

In a third embodiment, as shown in FIG. 7, the base 101 covers the top, bottom, and sides of the DBR layer 102, that is, the base 101 includes a bottom base located under the bottom of the DBR layer 102, side bases located on the sides of the DBR layer 102, and a top base located on the top of the DBR layer 102. The base 101 is provided on the top, bottom, and sides of the DBR layer 102, so that the base 101 covers the DBR layer 102 in all directions, reducing the risk of DBR layer 102 decomposition and improving the stability of the DBR layer 102.

A material of base 101 can include at least one of Si (silicon), SiC (silicon carbide), AlN (aluminum nitride), SiO₂ (silicon dioxide), SiN (silicon nitride), or diamond. By setting the base 101 in the above way, it can meet various usage needs, is easy to prepare the base 101, and has low cost. Moreover, for the base 101 using SiC material, the composite substrate 100 has mature production technology, good device quality, high stability, high mechanical strength, and is easy to dispose and clean. For the base 101 using Si material, the composite substrate 100 has excellent thermal conductivity and extend the lifespan of the device. For the base 101 using AlN material, the composite substrate 100 has excellent thermal, mechanical, chemical, and electrical properties, which is not only one of the best materials for preparing high-temperature, high-frequency and high-power electronic devices, but also can be used as a substrate material for GaN based blue semiconductor device structures.

It should be noted that a light transmittance of light of at least one wavelength passing through the top base and the growing substrate 103 exceeds 70%, reducing light loss. When the material of the base 101 is Si, the thickness of the top base should not exceed 100 nm to ensure the transparency of the top base.

The material of the DBR layer 102 includes a SiN layer and a SiO₂ layer that are periodically stacked, a SiO₂ layer and an Al₂O₃ layer that are periodically stacked, an AlN layer and an Al₂O₃ layer that are periodically stacked, or a fluorine doped SiO₂ layer and a SiO₂ layer that are periodically stacked, to meet various usage needs.

The material of the growing substrate 103 is at least one of Si, Al₂O₃ (sapphire), or AlN, to meet various usage needs. When the material of the growing substrate 103 is Si, the thickness of the growing substrate 103 is less than 100 nm to ensure the transparency of the growing substrate 103. In an embodiment, the material of the growing substrate 103 is Si, and the thickness of the growing substrate 103 is 40-60 nm, such as 40 nm, 50 nm, or 60 nm.

The composite substrate 100 further includes a buffer layer 104, which is prepared on the top surface of the growing substrate 103, i.e., the buffer layer 104 is prepared on a side of the growing substrate 103 far from the DBR layer 102. The buffer layer 104 plays a transitional role for the subsequent epitaxial structure and a heteroepitaxy on the growth substrate, so as to improve the crystal quality of the subsequent epitaxial structure.

A material of the buffer layer 104 is group III nitride. In an example, the material of the buffer layer 104 is GaN or AlGaN. GaN and AlGaN can effectively reduce external quantum efficiency decay and improve light-emitting efficiency, and the preparation process of GaN and AlGaN is mature and cost-effective.

The steps of preparing the composite substrate 100 include steps S10-S60.

In step S10, the base plate is provided.

In step S20, the bottom base is prepared on the base plate.

In step S30, the DBR layer 102 is deposited on the bottom base.

In step S40, the side bases and the top base are deposited on the DBR layer 102.

In step S50, the growing substrate 103 is bonded on the top of the top base.

In step S60, the buffer layer 104 is epitaxially grown on the top of the growing substrate 103, to complete the preparation of the composite substrate 100.

In step S10, a material of the base plate can include a glass base plate. The cost of glass base plate is low, so that it is easy to peel off the bottom base subsequently.

In step S20, the bottom base can be deposited on the base plate by an evaporation process or by the PVD (Physical Vapor Deposition) process. In some embodiments, the bottom base is deposited on the base plate through an evaporation process, which is the same process as the subsequent deposition of the side bases and the top base, saving preparation costs.

In step S30, in some embodiments, the DBR layer 102 is deposited by a PVD process.

When the DBR layer 102 is deposited, the DBR layer 102 is deposited in all regions of the composite substrate 100 that receive light, that is, the DBR layer 102 is continuously set on the bottom base, that is, the DBR layer 102 is deposited in all parts of the bottom base. When the composite substrate 100 is applied to a semiconductor device structure, layers in the DBR layer 102 in the composite substrate 100 of the same semiconductor device structure are continuous and uninterrupted layer structures.

In step S50, the growing substrate 103 is prepared on the base 101 through a bonding process. Compared to the epitaxial process, the bonding process is simple and cost-effective, which can effectively reduce the preparation cost of the composite substrate 100.

In step S60, the buffer layer 104 can be epitaxially grown by the Chemical Vapor Deposition (CVD) process. Before epitaxial growth of the buffer layer 104, the base 101 is first peeled off from the base plate by using a laser peeling process to reduce the performance impact of peeling the base 101 on the buffer layer 104. The semiconductor device structure provided in the present disclosure includes the above composite substrate 100. In the semiconductor device structure, the DBR layer 102 is integrated into a composite substrate, and the growing substrate 103 can be prepared on the top layer of the DBR layer 102 by a bonding process, which requires a lower temperature than the high-temperature epitaxial process, reducing the risk of decomposition of the DBR layer 102 during the preparation of the growing substrate103, thereby, improving the stability of the DBR layer 102. At the same time, the DBR layer 102 is integrated into the composite substrate, which has little impact on the performance of the DBR layer 102 and the substrate. Moreover, the growing substrate 103 is prepared by a bonding process. Compared to the epitaxial process, the bonding process is simple and cost-effective, which can effectively reduce the preparation cost for the composite substrate 100.

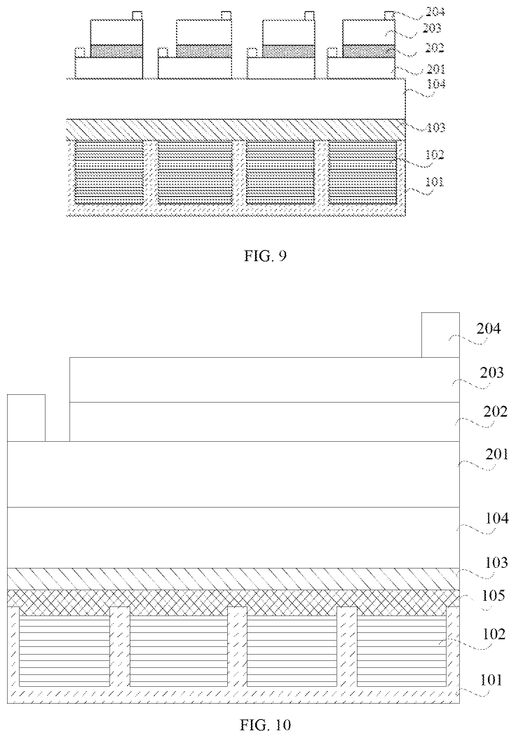

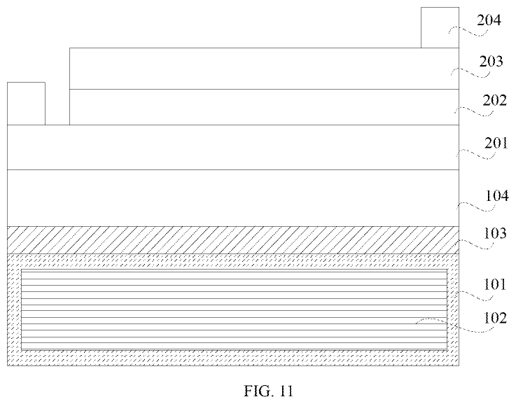

The structure of the semiconductor device using the above composite substrate 100 is not limited. As shown in FIGS. 8 to 11, the semiconductor device structure includes a composite substrate 100 and an LED unit. The LED unit includes a first semiconductor layer 201, an active layer 202, a second semiconductor layer 203, and a metal electrode 204. The conductive types of the first semiconductor layer 201 and the second semiconductor layer 203 are opposite.

Multiple DBR layers 102 can be provided in the base 101, and multiple LED units can be provided, with each LED unit corresponding to one DBR layer 102. The composite substrate 100 includes multiple DBR layers, and cross-sectional areas of the multiple DBR layers 102 are different; or spaces between adjacent DBR layers 102 of the multiple DBR layers 102 are different, as shown in FIGS. 7 and 8. By setting in the above way, various usage needs of semiconductor device structures can be met.

After considering and practicing the disclosure of the specification, other embodiments of the present disclosure will be readily apparent to those skilled in the art. The present disclosure is intended to cover any modification, use or adaptation of the present disclosure. These modifications, uses or adaptations follow the general principles of the present disclosure and include common knowledge and conventional technical means in the technical field that are not disclosed in the present disclosure. The specification and embodiments herein are intended to be illustrative only and the real scope and spirit of the present disclosure are indicated by the following claims of the present disclosure.

It is to be understood that the present disclosure is not limited to the precise structures described above and shown in the accompanying drawings and may be modified or changed without departing from the scope of the present disclosure. The scope of the present disclosure is limited only by the attached claims.

What is claimed is:

1. A composite substrate, comprising:
a base;
a DBR(distributed Bragg reflector) layer on a side of the base; and
a growing substrate on a side of the DBR layer far from the base.

2. The composite substrate according to claim 1, wherein the composite substrate further comprises a protecting layer, wherein
the protecting layer covers a top surface of the DBR layer, or
the protecting layer covers a top surface and a side surface of the DBR layer.

3. The composite substrate according to claim 2, wherein a light transmittance of light of at least one wavelength passing through the protecting layer and the growing substrate exceeds 70%.

4. The composite substrate according to claim 1, wherein the base comprises a patterned base, and the top surface of the base is provided with a trench, and the DBR layer is in the trench.

5. The composite substrate according to claim 4, wherein
the DBR layer protrudes from the top surface of the base;
a top surface of the DBR layer is flush with the top surface of the base; or
a top surface of the DBR layer is lower than the top surface of the base.

6. The composite substrate according to claim 4, wherein the composite substrate further comprises a protecting layer, wherein
the protecting layer only covers the DBR layer, and the growing substrate is bonded to the base; or
the protecting layer covers the DBR layer and the base, and the growing substrate is bonded to the protecting layer.

7. The composite substrate according to claim 6, wherein a top surface of the protecting layer is flush with the top surface of the base, and the growing substrate is bonded with the protecting layer and the base.

8. The composite substrate according to claim 2, wherein a material of the protecting layer comprises at least one of Si, Al₂O₃, or AlN.

9. The composite substrate according to claim 1, wherein a material of the base comprises at least one of Si, SiC, AlN, Al₂O₃, or diamond.

10. The composite material according to claim 1, wherein the growing substrate comprises a monocrystalline-material layer.

11. The composite substrate according to claim 10, wherein a material of the growing substrate comprises at least one of Si, Al₂O₃, or AlN.

12. The composite substrate according to claim 11, wherein the material of the growing substrate is Si, and a thickness of the growing substrate is less than 100 nm.

13. The composite substrate according to claim 1, wherein a material of the DBR layer comprises a SiN layer and a SiO₂ layer that are periodically stacked, a SiO₂ layer and an Al₂O₃ layer that are periodically stacked, an AlN layer and an Al₂O₃ layer that are periodically stacked, or a fluorine doped SiO₂ layer and a SiO₂ layer that are periodically stacked.

14. A semiconductor device structure, comprising a composite substrate and an LED unit, wherein
the composite substrate comprises:
a base;
a DBR layer on a side of the base; and
a growing substrate on a side of the DBR layer far from the base; and
the LED unit comprises:
a first semiconductor layer, on the growing substrate;
an active layer, on a surface of the first semiconductor layer; and
a second semiconductor layer, on a surface of the active layer;
wherein conductive types of the first semiconductor layer and the second semiconductor layer are opposite.

15. The semiconductor device structure according to claim 14, wherein the base is provided with a plurality of the DBR layers, and there are a plurality of the LED units, each of the plurality of the LED units corresponds to one of the plurality of the DBR layers.

16. The semiconductor device structure according to claim 14, wherein the composite substrate comprises a plurality of the DBR layers, and at least one of:
cross-sectional areas of the plurality of the DBR layers are different; or
spaces between adjacent DBR layers of the plurality of the DBR layers are different.
